(19) United States
(12) Patent Application Publication
(10) Pub. No.: US 2015/0279486 A1
(43) Pub. Date: Oct. 1, 2015

(54) SYSTEM AND METHOD FOR ADDING ERROR PROTECTION CAPABILITY TO A DIGITAL LOGIC CIRCUIT

(71) Applicant: Emulex Corporation, Costa Mesa, CA (US)

(72) Inventors: William Leavitt, Lexington, MA (US); Lawrence Rubin, Austin, TX (US)

(73) Assignee: Emulex Corporation, Costa Mesa, CA (US)

(21) Appl. No.: 14/225,816

(22) Filed: Mar. 26, 2014

(51) Int. Cl. G11C 29/42; G11C 29/44

(52) U.S. Cl. CPC G11C 29/42; G11C 29/44

(57) ABSTRACT

A system and method for adding error protection capability to a digital logic circuit, for example including random storage logic. Various aspects of the present disclosure, for example, comprise providing error protection against soft errors that occur during operation of digital logic circuitry.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### SEQUENCE LISTING

[Not Applicable]

### MICROFICHE/COPYRIGHT REFERENCE

[Not Applicable]

### BACKGROUND

Conventional electrical circuitry, for example digital logic circuitry, may generally have inadequate protection against errors. Further limitations and disadvantages of conventional and traditional approaches will become apparent to one of skill in the art, through comparison of such approaches with the disclosure as set forth in the remainder of the present application with reference to the drawings.

### BRIEF DESCRIPTION OF SEVERAL VIEWS OF THE DRAWINGS

FIG. 1 is a schematic diagram of an electrical circuit comprising error protection, in accordance with various aspects of the present disclosure.

FIG. 2 is a schematic diagram of an electrical circuit comprising error protection, in accordance with various aspects of the present disclosure.

FIG. 3 is a schematic diagram of an electrical circuit comprising error protection, in accordance with various aspects of the present disclosure.

FIG. 4 shows a flow diagram of an example method for protecting an electrical circuit, in accordance with various aspects of the present disclosure.

FIG. 5 is a diagram illustrating circuit component selection, in accordance with various aspects of the present disclosure.

FIG. 6 is a diagram illustrating a system for protecting an electrical circuit, in accordance with various aspects of the present disclosure.

### SUMMARY

A system and method for adding error detection capability to a digital logic circuit, substantially as shown in and/or described in connection with at least one of the figures, as set forth more completely in the claims.

### DETAILED DESCRIPTION OF VARIOUS ASPECTS OF THE DISCLOSURE

The following discussion will present various aspects of the present disclosure by providing various examples thereof. Such examples are non-limiting, and thus the scope of various aspects of the present disclosure should not necessarily be limited by any particular characteristics of the provided examples. In the following discussion, the phrases “for example” and “e.g.” are non-limiting and are generally synonymous with “by way of example and not limitation,” “for example and without limitation,” and the like.

The following discussion will at times utilize the phrase “A and/or B.” Such phrase should be understood to mean A, or B, or both A and B.

The following discussion will at times utilize the phrase “operates to” in discussing functionality performed by particular hardware, including hardware operating in accordance with software instructions. The phrase “operates to” includes “operates when enabled to”. For example, a module that operates to perform a particular operation, but only after receiving a signal to enable such operation, is included by the phrase “operates to.”

Modern electrical circuitry, for example digital logic circuitry, is increasingly susceptible to errors. Such errors, for example, may comprise hard errors due to circuit failure and/or soft errors caused for example by background radiation. A soft error, for example, might cause a storage element, for example a synchronous logic device (SLD), to errantly change state. A soft error, for example, might also cause a combination logic device to errantly change state.

Parity checking is an example method for detecting such errors in digital logic. Standard methods of adding parity checking to digital logic (e.g., random digital logic) are, however, inadequate. Other example methods for handling errors in digital logic design include duplicating (e.g., in-whole or in-part) the circuitry being protected, which results in substantial increases in circuit size and power consumption. Further example methods for handling errors in digital logic design include using components that are hardened against errors (e.g., soft errors), but such hardened components is expensive and involves using larger and slower components. Various aspects of the present disclosure overcome the above-mentioned deficiencies. For example, while using hardened components and duplicate circuitry is still possible if desired, such designs are not necessary.

Another issue with present error detection (e.g., parity error detection) is that the circuitry performing the error detection adversely affects the performance of the circuitry being tested, for example including the addition of signal delay. Various aspects of the present disclosure avoid or minimize the adverse effects of signal delay by, for example, focusing error detection on components that are less susceptible to the adverse effects of signal delay.

In general, various aspects of this disclosure provide a system and method that, for example, allows for providing error detection in random (or irregular) logic, instead of for example only on buses and RAM devices with regular repeatable circuit structures.

The present disclosure will now provide non-limiting examples of systems and methods for providing error protection in an electrical circuit. As mentioned above and emphasized again, the characteristics of such examples are non-limiting. Accordingly, various aspects of this disclosure should not be limited by any particular characteristics of any particular example unless such limiting is explicitly stated.

For example, the following discussion will present various aspects of the disclosure by providing a variety of examples including sequential logic devices (SLDs). Such presentation is merely for illustrative clarity and not for limitation. For example, the scope of various aspects of the disclosure presented in terms of SLDs (e.g., devices under test and/or devices performing the testing and/or ancillary devices) applies to storage elements in general. For example, such a storage element may comprise characteristics of a D-flipflop with a clock input, a D-flipflop with clock and synchronous clear inputs, a D-flipflop with clock and asynchronous clear inputs, a D-flipflop with clock and synchronous preset inputs, a D-flipflop with clock and asynchronous preset inputs, a D-flipflop with clock and synchronous clear and preset inputs, a D-flipflop with clock and asynchronous clear and preset inputs, a latch with latch enable input, a latch with latch enable and asynchronous clear input, a latch with latch enable and asynchronous preset input, a scan type of storage element, a non-scan type of storage element, etc. Thus, the scope of the various aspects of the present disclosure should not be limited by characteristics of SLDs unless explicitly claimed.

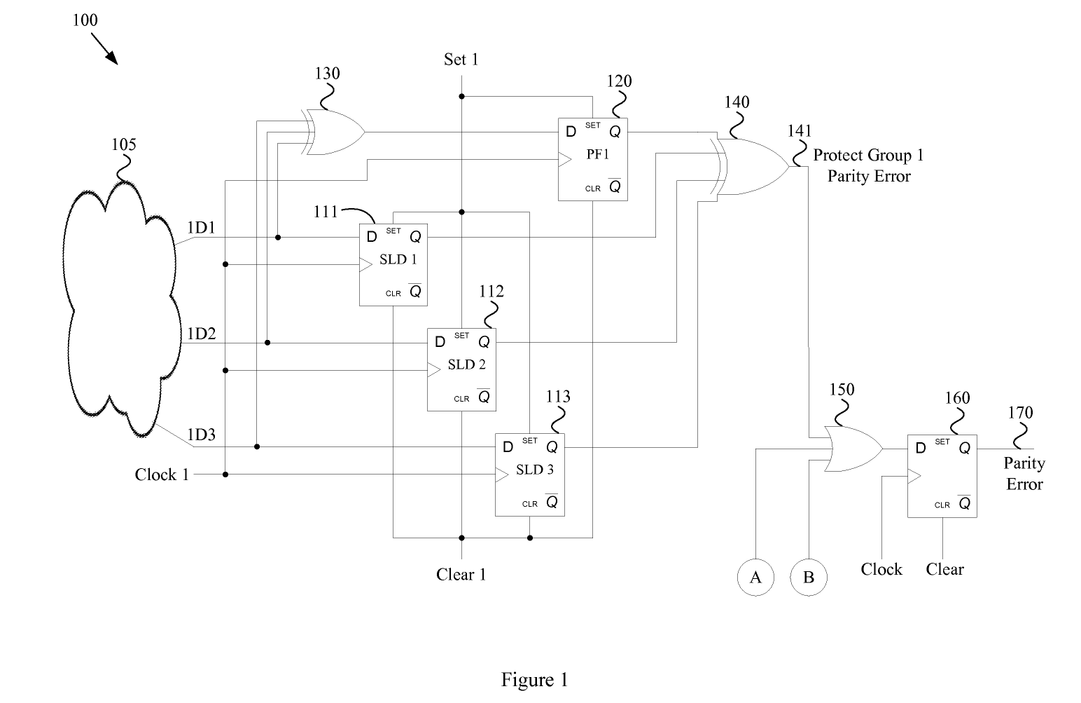

Turing first to FIG. 1, such figure is a schematic diagram of an electrical circuit 100 comprising error protection, in accordance with various aspects of the present disclosure.

The electrical circuit 100 is only shown in-part for illustrative clarity. The illustrated electrical circuit 100 may, for example, comprise a portion of any of a large variety of electrical circuits. Such electrical circuits may, for example, comprise network interface circuitry (e.g., optical and/or electrical network interface chips), processing circuitry, register circuitry, multi-media processing circuitry, wired and/or wireless and/or optical communication circuitry, application-specific integrated circuits, baseband processors, etc.

The electrical circuit 100 may, for example, comprise an upstream signal source 105 that provides digital logic signals (e.g., 1D1, 1D2, and 1D3) to downstream components. The signal source 105 may, for example, comprise one or more immediately preceding logic devices (e.g., storage elements, for example sequential logic devices, combinational logic devices, etc.), analog-to-digital converters, communication buses, etc.

The electrical circuit 100 may, for example, comprise a first sequential logic device (SLD 1) 111, a second sequential logic device (SLD 2) 112, and a third sequential logic device (SLD 3) 113. The first SLD 111 may, for example, receive a digital signal 1D1 from the signal source 105. Also the second SLD 112 may, for example, receive a digital signal 1D2 from the signal source 105. Additionally the third SLD 113 may, for example, receive a digital signal 1D3 from the signal source 105. The SLDs 111, 112, and 113 are illustrated as D flip-flops, but may comprise characteristics of any of a large variety of sequential logic devices (e.g., any type of flip flop, any type of other data storage element, etc.).

The first SLD 111, second SLD 112, and third SLD 113 are each coupled to a same clock signal (Clock_1). The clock signal (Clock_1) may comprise characteristics of any of a variety of clock signals. For example, Clock_1 may be an unmodified system clock (e.g., a sole system clock or one of a plurality of systems clocks). Also for example, Clock_1 may be a gated version of the system clock signals. Operationally, the respective inputs (1D1, 1D2, and 1D3) of the SLDs (111, 112, and 113) are stored in the SLDs (111, 112, and 113) when the SLDs (111, 112, and 113) are clocked (e.g., positive-edge clocked, negative-edge clocked, level clocked, etc.) by Clock_1.

The first SLD 111, second SLD 112, and third SLD 113 provide an example of a group of SLDs that will be tested as a group for a parity error within the group. Thus, they provide an example of what at times will be referred to herein as a “parity protect group.” A parity protect group may comprise any number of circuit elements (e.g., SLDs) under test. For example, a parity protect group may comprise an even number of SLDs (e.g., 16 SLDs, 32 SLDs, 64 SLDs, 128 SLDs, an even number that is not a power of 2, etc.). Also for example a parity protect group may comprise an odd number of SLDs (e.g., 15 SLDs, 17, SLDs, 31 SLDs, 33 SLDs, 63 SLDs, 65 SLDs, 127 SLDs, 129 SLDs, an odd number that is not 1 greater or less than a power of 2, etc.). As will be discussed later, in various example implementations, it may be advantageous to have an odd number of circuit elements under test instead of an even number.

The first SLD 111, second SLD 112, and third SLD 113 are each coupled to a same clear signal (Clear_1). The clear signal (Clear_1) may comprise characteristics of any of a variety of clear signals. For example, Clear_1 may be generated by various components of the electrical circuit 100 during normal operation of the electrical circuit, generated by test and/or troubleshooting circuitry, etc. Operationally, the respective outputs of the SLDs (111, 112, and 113) are cleared in response to the Clear_1 signal.

The first SLD 111, second SLD 112, and third SLD 113 are each coupled to a same set signal (Set_1). The set signal (Set_1) may comprise characteristics of any of a variety of set signals. For example, the Set_1 signal may be generated by various components of the electrical circuit 100 during normal operation of the electrical circuit, generated by test and/or troubleshooting circuitry, etc. Operationally, the respective outputs of the SLDs (111, 112, and 113) are set in response to the Set_1 signal.

The electrical circuit 100 may also, for example, comprise various circuit elements that operate together to monitor the parity of the circuit elements (e.g., SLDs) under test. Such circuit elements may, for example, comprise the first exclusive OR (XOR) gate 130, first parity SLD 120, second XOR gate 140, report point OR gate 150, and report point SLD 160. Each of such circuit elements will now be discussed.

The first XOR gate 130 may, for example, comprise a single XOR gate or an XOR tree or any logic structure that performs the XOR function. Only one first XOR gate 130 is shown at this location in the electrical circuit 100 for illustrative clarity. The first XOR gate 130 may receive the respective input signals (1D1, 1D2, and 1D3) that are input to each of the SLDs (111, 112, and 113), and output a signal indicative of the XOR function applied to such input signals. The output of the first XOR gate 130 is provided to the input of the first parity SLD 120. Operationally, the first XOR gate 130 may asynchronously calculate the parity of the signals (1D1, 1D2, and 1D3) that are input to the SLDs (111, 112, and 113) under test.

The first parity SLD 120 (also referred to herein as a parity test SLD) is illustrated as a D flip-flop that receives the output signal from the first XOR gate 130 at its D input, but the first parity SLD 120 may be any of a variety of different types of sequential logic device and/or other data storage element. The first parity SLD 120 may, for example, receive the same clock input signal (e.g., Clock_1) that is received by the SLDs (111, 112, and 113) under test. Operationally, the first parity SLD 120 captures the parity of the input signals (1D1, 1D2, and 1D3) as they are clocked into the SLDs (111, 112, and 113) under test.

The second XOR gate 140 receives as input the respective output signals from the SLDs (111, 112, and 113) under test and the output signal from the first parity SLD 120. The second XOR gate 140 thus asynchronously calculates the parity of the output signals from the SLDs (111, 112, and 113) under test and compares the calculated parity to the parity stored in the first parity SLD 120. The results of the test are output from the second XOR gate 140 as signal 141, which is also called the “Protect Group 1 Parity Error.” For example, operationally, if an output of one of the SLDs (111, 112, and 113) under test errantly changes, for example as a result of a soft error induced state change, such an errant change will be reflected in the Protect Group 1 Parity Error signal 141. Similarly, an errant change in the first parity SLD 120 will also be reflected in the Protect Group 1 Parity Error signal 141. As discussed above with regard to the first XOR gate 130, the second XOR gate 140 may comprise a single XOR gate, an XOR tree, or any type of circuit that performs an XOR function.

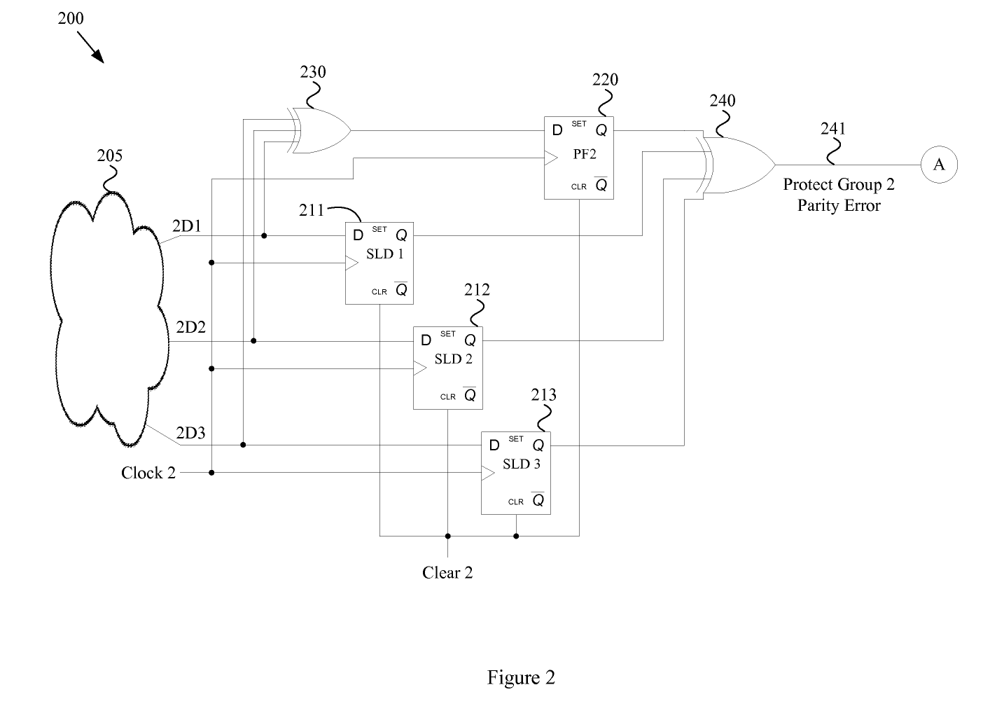

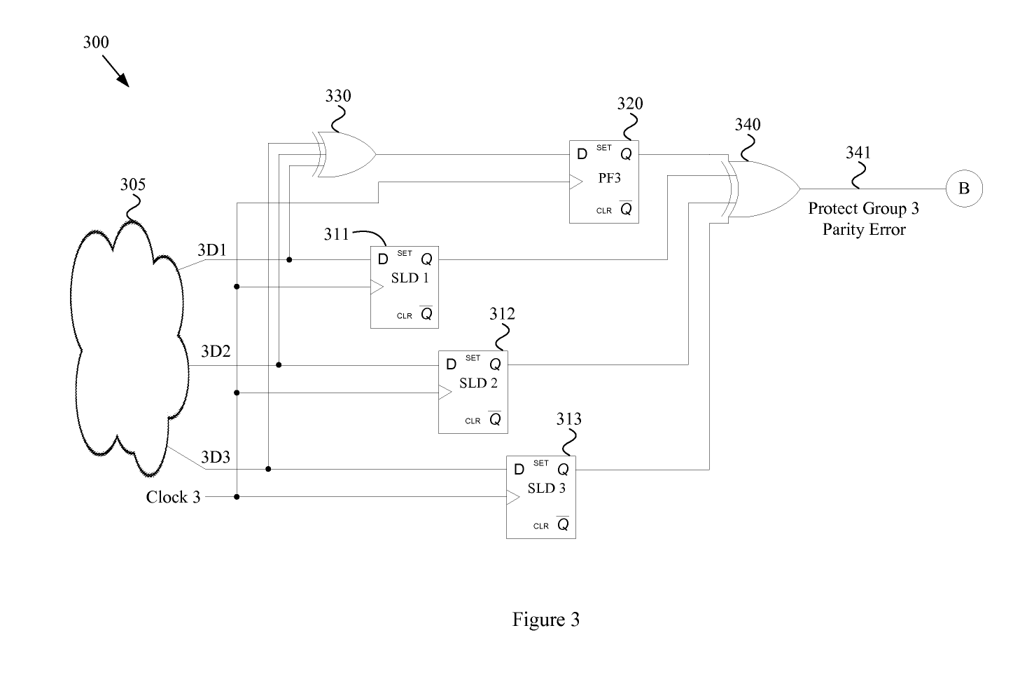

The report point OR gate 150 receives as input the Protect Group 1 Parity Error signal 141. The first OR gate 150 may also receive as input respective Protect Group Parity Error signals from other parity protect groups. Example input signals A and B, for example, correspond to parity protect group circuitry shown in FIGS. 2 and 3 respectively (and discussed below). The first OR gate 150 may thus aggregate Protect Group Parity Error signals from a plurality of parity protect groups. As discussed above with regard to the first XOR gate 130, the report point OR gate 150 may comprise a single OR gate, an OR tree, or any type of circuit that performs an OR function. The output of the report point OR gate 150 is provided to the input of the report point SLD 160. Operationally, the report point OR gate 150 may asynchronously determine the existence of a parity error detected in any of the parity protect groups to which it is coupled.

The report point SLD 160 is illustrated as a D flip-flop that receives the output signal from the report point OR gate 150 at its D input, but the report point SLD 160 may be any of a variety of different types of sequential logic device and/or other data storage element. The report point SLD 160 receives a clock signal (Clock). The Clock signal may, for example, be the same as the Clock_1 signal or may be different. For example, the Clock signal may be a non-gated system clock and the Clock_1 signal may be a gated system clock, or vice versa. Also for example, the Clock signal and the Clock_1 signal may be different gated versions of a same system clock. The report point SLD 160 may also receive a Clear signal (Clear). The Clear signal may, for example, be the same as the Clear_1 signal or may be different. The report point SLD 160 may output a Parity Error signal that, for example, represents the parity error state of each of a plurality of parity protect groups that provide respective parity error signals to the report point OR gate 150. For example, a parity error detected in any of such parity protect groups may get clocked into the report point SLD 160 and be output as the Parity Error signal 170.

The Parity Error signal 170 may then, for example, be provided to processing circuitry that performs any of a variety of error reporting and/or handling operations. For example, the Parity Error signal 170 may be provided to system surveillance circuitry, system recovery circuitry, system restore circuitry, etc. For example, in an example scenario in which the Parity Error signal 170 indicates that there has been a parity error in one of the parity protect groups corresponding to the report point SLD 160, corresponding hardware and/or software can be reset and/or restored, the parity protect groups can be reset and/or re-clocked, etc., before further damage is done.

The report point OR gate 150 and report point SLD 160 may, for example, generally receive and/or aggregate parity error signals from parity protect groups that are part of a same general clock domain (for example, corresponding to a same system clock). For example, the report point OR gate and report point SLD 160 may receive and/or aggregate parity error signals from a first parity protect group that is clocked by the non-gated system clock, a second parity protect group that is also clocked by the non-gated system clock, a third parity protect group that is clocked by a first gated system clock, a fourth parity protect group that is clocked by a second gated system clock, a fifth parity protect group that is clocked by the second gated system clock, etc.

The parity protect group shown in FIG. 1 may, for example, be characterized by a respective set of control signal inputs. For example, the respective set of control signal inputs may comprise a clock net (e.g., clocked by the Clock_1 signal), a clear (or reset) net (e.g., cleared by the Clear_1 signal), and a set (or preset or load) net (e.g., set by the Set_1 signal). Such an example set of control signal inputs, for example based on three control signal nets, may also be referred to herein as a triplet. As will be seen in the following discussion of FIGS. 2 and 3, other parity protect groups may be characterized by different respective sets of control signal inputs. Other parity protect groups may also be characterized by a same set of control signal inputs as the parity protect group shown in FIG. 1.

Turning to FIG. 2, such figure is a schematic diagram of an electrical circuit 200 comprising error protection, in accordance with various aspects of the present disclosure. The electrical circuit 200 may, for example, share any or all characteristics with the example electrical circuit 100 illustrated in FIG. 1 and discussed previously.

The electrical circuit 200 is only shown in-part for illustrative clarity. The illustrated electrical circuit 200 may, for example, comprise a portion of any of a large variety of electrical circuits. Such electrical circuits may, for example, comprise network interface circuitry (e.g., optical and/or electrical network interface chips), processing circuitry, register circuitry, multi-media processing circuitry, wired and/or wireless and/or optical communication circuitry, application-specific integrated circuits, baseband processors, etc.

The electrical circuit 200 may, for example, comprise an upstream signal source 205 that provides digital logic signals (e.g., 2D1, 2D2, and 2D3) to downstream components. The signal source 205 may, for example, comprise one or more immediately preceding logic devices (e.g., sequential and/or combination logic devices), analog-to-digital converters, communication buses, etc. The signal source 205 may, for example, comprise the same signal source 105 as illustrated in FIG. 1 or may be different. The digital logic signals (e.g., 2D1, 2D2, and 2D3) may similarly be the same as the digital logic signals (e.g., 1D1, 1D2, and 1D3) shown in FIG. 1 or may be different.

The electrical circuit 200 may, for example, comprise a first sequential logic device (SLD 1) 211, a second sequential logic device (SLD 2) 212, and a third sequential logic device (SLD 3) 213. The first SLD 211 may, for example, receive a digital signal 2D1 from the signal source 205. Also the second SLD 212 may, for example, receive a digital signal 2D2 from the signal source 205. Additionally the third SLD 213 may, for example, receive a digital signal 2D3 from the signal source 205. The SLDs 211, 212, and 213 are illustrated as D flip-flops, but may comprise characteristics of any of a large variety of sequential logic devices (e.g., any type of flip flop, any type of other data storage element, etc.).

The first SLD 211, second SLD 212, and third SLD 213 are each coupled to a same clock signal (Clock_2). The clock signal Clock_2 may, for example, be the same as the clock signal Clock_1 shown in FIG. 1 or may be different. The clock signal (Clock_2) may comprise characteristics of any of a variety of clock signals. For example, Clock_2 may be an unmodified system clock (e.g., a sole system clock or one of a plurality of systems clocks). Also for example, Clock_2 may be a gated version of the system clock signals. Operationally, the respective inputs (2D1, 2D2, and 2D3) of the SLDs (211, 212, and 213) are stored in the SLDs (211, 212, and 213) when the SLDs (211, 212, and 213) are clocked (e.g., positive-edge clocked, negative-edge clocked, level clocked, etc.) by Clock_2.

The first SLD 211, second SLD 212, and third SLD 213 provide an example of a group of SLDs that will be tested as a group for a parity error within the group. Thus, they provide an example (e.g., another example in addition to the example shown in FIG. 1) of what at times will be referred to herein as a “parity protect group.” A parity protect group may comprise any number of circuit elements (e.g., SLDs) under test. For example, a parity protect group may comprise an even number of SLDs (e.g., 16 SLDs, 32 SLDs, 64 SLDs, 128 SLDs, an even number that is not a power of 2, etc.). Also for example a parity protect group may comprise an odd number of SLDs (e.g., 15 SLDs, 17, SLDs, 31 SLDs, 33 SLDs, 63 SLDs, 65 SLDs, 127 SLDs, 128 SLDs, an odd number that is not 1 greater or less than a power of 2, etc.). As will be discussed later, in various example implementations, it may be advantageous to have an odd number of circuit elements under test instead of an even number.

The first SLD 211, second SLD 212, and third SLD 213 are each coupled to a same clear signal (Clear_2). The clear signal (Clear_2) may comprise characteristics of any of a variety of clear signals. The clear signal Clear_2 may, for example, be the same as the clear signal Clear_1 shown in FIG. 1 or may be different. For example, Clear_2 may be generated by various components of the electrical circuit 200 during normal operation of the electrical circuit, generated by test and/or troubleshooting circuitry, etc. Operationally, the respective outputs of the SLDs (211, 212, and 213) are cleared in response to the Clear_{—}2 signal.

Different from the example shown in FIG. 1, the first SLD 211, second SLD 212, and third SLD 213 are not coupled to a set signal (e.g., like the set signal Set_1 of FIG. 1).

The electrical circuit 200 may also, for example, comprise various circuit elements that operate together to monitor the parity of the circuit elements (e.g., SLDs) under test. Such circuit elements may, for example comprise the first exclusive OR (XOR) gate 230, first parity SLD 220, and second XOR gate 240. As will be discussed below, the output of the second XOR gate 240, labeled output A, may be input to the report point OR gate 150 of FIG. 1. Each of such circuit elements will now be discussed.

The first XOR gate 230 may, for example, comprise a single XOR gate or an XOR tree or any logic structure that performs the XOR function. Only one first XOR gate 230 is shown at this location in the electrical circuit 200 for illustrative clarity. The first XOR gate 230 may receive the respective input signals (2D1, 2D2, and 2D3) that are input to each of the SLDs (211, 212, and 213), and output a signal indicative of the XOR function applied to such input signals. The output of the first XOR gate 230 is provided to the input of the first parity SLD 220. Operationally, the first XOR gate 230 may asynchronously calculate the parity of the signals (2D1, 2D2, and 2D3) that are input to the SLDs (211, 212, and 213) under test.

The first parity SLD 220 (also referred to herein as a parity test SLD) is illustrated as a D flip-flop that receives the output signal from the first XOR gate 230 at its D input, but the first parity SLD 220 may be any of a variety of different types of sequential logic device and/or other data storage element. The first parity SLD 220 may, for example, receive the same clock input signal (i.e., Clock_2) that is received by the SLDs (211, 212, and 213) under test. Operationally, the first parity SLD 220 captures the parity of the input signals (2D1, 2D2, and 2D3) as they are clocked into the SLDs (211, 212, and 213) under test.

The second XOR gate 240 receives as input the respective output signals from the SLDs (211, 212, and 213) under test and the output signal from the first parity SLD 220. The second XOR gate 240 thus asynchronously calculates the parity of the output signals from the SLDs (212, 212, and 213) under test and compares the calculated parity to the parity stored in the first parity SLD 220. The results of the test are output from the second XOR gate 240 as signal 241, which is also called the “Protect Group 2 Parity Error.” For example, operationally, if an output of one of the SLDs (211, 212, and 213) under test errantly changes, for example as a result of a soft error induced state change, such an errant change will be reflected in the Protect Group 2 Parity Error signal 241. As discussed above with regard to the first XOR gate 230, the second XOR gate 240 may comprise a single XOR gate, an XOR tree, or any type of circuit that performs an XOR function. As illustrated by the output bubble labeled “A,” the Parity Group 2 Parity Error signal is output to the corresponding input bubble labeled “A” in FIG. 1.

Referring briefly back to FIG. 1, the report point OR gate 150 receives as input the Protect Group 2 Parity Error signal 241. As mentioned previously, the first OR gate 150 may also receive as input respective Protect Group Parity Error signals from other parity protect groups. Example input signal B, for example, corresponds to parity protect group circuitry shown in FIG. 3 (discussed below). Please refer to the previous discussion of FIG. 1 for the discussion of the operation of the report point OR gate 150 and the report point SLD 160.

The parity protect group shown in FIG. 2 may, for example, be characterized by a respective set of control signal inputs. For example, the respective set of control signal inputs may comprise a clock net (e.g., clocked by the Clock_{—}2 signal), a clear (or reset) net (e.g., cleared by the Clear_{—}2 signal), and a set (or preset) net (e.g., a null net, since the SLDs 211, 212, and 213 of the electrical circuit 200 of FIG. 2 are not coupled to a set signal). Such an example set of control signal inputs, for example based on three control signal input nets, may also be referred to herein as a triplet. As was seen in the previous discussion of FIG. 1 and as will be seen in the following discussion of FIG. 3, other parity protect groups may be characterized by different respective sets of control signal inputs. Other parity protect groups may also be characterized by a same set of control signal inputs as the parity protect group shown in FIG. 2.

Turning to FIG. 3, such figure is a schematic diagram of an electrical circuit 300 comprising error protection, in accordance with various aspects of the present disclosure. The electrical circuit 300 may, for example, share any or all characteristics with the example electrical circuit 100 illustrated in FIG. 1 and discussed previously and with the example electrical circuit 200 illustrated in FIG. 2 and discussed previously.

The electrical circuit 300 is only shown in-part for illustrative clarity. The illustrated electrical circuit 300 may, for example, comprise a portion of any of a large variety of electrical circuits. Such electrical circuits may, for example, comprise network interface circuitry (e.g., optical and/or electrical network interface chips), processing circuitry, register circuitry, multi-media processing circuitry, wired and/or wireless and/or optical communication circuitry, application-specific integrated circuits, baseband processors, etc.

The electrical circuit 300 may, for example, comprise an upstream signal source 305 that provides digital logic signals (e.g., 3D1, 3D2, and 3D3) to downstream components. The signal source 305 may, for example, comprise one or more immediately preceding logic devices (e.g., sequential and/or combination logic devices), analog-to-digital converters, communication buses, etc. The signal source 305 may, for example, comprise the same signal source 105 as illustrated in FIG. 1 and/or the same signal source 205 as illustrated in FIG. 2, or may be different. The digital logic signals (e.g., 3D1, 3D2, and 3D3) may similarly be the same as the digital logic signals (e.g., 1D1, 1D2, and 1D3) shown in FIG. 1 and/or the digital logic signals (e.g., 2D1, 2D2, and 2D3) shown in FIG. 2, or may be different.

The electrical circuit 300 may, for example, comprise a first sequential logic device (SLD 1) 311, a second sequential logic device (SLD 2) 312, and a third sequential logic device (SLD 3) 313. The first SLD 311 may, for example, receive a digital signal 3D1 from the signal source 305. Also the second SLD 212 may, for example, receive a digital signal 3D2 from the signal source 305. Additionally the third SLD 313 may, for example, receive a digital signal 3D3 from the signal source 305. The SLDs 311, 312, and 313 are illustrated as D flip-flops, but may comprise characteristics of any of a large variety of sequential logic devices (e.g., any type of flip flop, any type of other data storage element, etc.).

The first SLD 311, second SLD 312, and third SLD 313 are each coupled to a same clock signal (Clock_3). The clock signal Clock_3 may, for example, be the same as the clock signal Clock_1 shown in FIG. 1 and/or the clock signal Clock_2 shown in FIG. 2, or may be different. The clock signal Clock_3 may comprise characteristics of any of a variety of clock signals. For example, the Clock_3 clock signal may be an unmodified system clock (e.g., a sole system clock or one of a plurality of systems clocks). Also for example, the Clock_3 clock signal may be a gated version of the system clock signals. Operationally, the respective inputs (3D1, 3D2, and 3D3) of the SLDs (311, 312, and 313) are stored in the SLDs (311, 312, and 313) when the SLDs (311, 312, and 313) are clocked (e.g., positive-edge clocked, negative-edge clocked, level clocked, etc.) by the Clock_3 clock signal.

The first SLD 311, second SLD 312, and third SLD 313 provide an example of a group of SLDs that will be tested as a group for a parity error within the group. Thus, they provide an example (e.g., another example in addition to the examples shown in FIG. 1 and FIG. 2) of what at times will be referred to herein as a “parity protect group.” A parity protect group may comprise any number of circuit elements (e.g., SLDs) under test. For example, a parity protect group may comprise an even number of SLDs (e.g., 16 SLDs, 32 SLDs, 64 SLDs, 128 SLDs, and/or an even number that is not a power of 2, etc.). Also for example a parity protect group may comprise an odd number of SLDs (e.g., 15 SLDs, 17, SLDs, 31 SLDs, 33 SLDs, 63 SLDs, 65 SLDs, 127 SLDs, 129 SLDs, an odd number that is not 1 greater or less than a power of 2, etc.). As will be discussed later, in various example implementations, it may be advantageous to have an odd number of circuit elements under test instead of an even number.

Different from the examples shown in FIGS. 1 and 2, the first SLD 311, second SLD 312, and third SLD 313 of FIG. 3 are not coupled to a clear signal (e.g., like the clear signal Clear_1 of FIG. 1 and/or the clear signal Clear_2 of FIG. 2). Additionally, different from the example shown in FIG. 1, the first SLD 311, second SLD 312, and third SLD 313 of FIG. 3 are not coupled to a set signal (e.g., like the set signal Set_1 of FIG. 1).

The electrical circuit 300 of FIG. 3 may also, for example, comprise various circuit elements that operate together to monitor the parity of the circuit elements (e.g., SLDs) under test. Such circuit elements may, for example comprise the first exclusive OR (XOR) gate 330, first parity SLD 320, and second XOR gate 340. As will be discussed below, the output of the second XOR gate 340, labeled output B, may be input to the report point OR gate 150 of FIG. 1. Each of such circuit elements will now be discussed.

The first XOR gate 330 may, for example, comprise a single XOR gate or an XOR tree or any logic structure that performs the XOR function. Only one first XOR gate 330 is shown at this location in the electrical circuit 300 for illustrative clarity. The first XOR gate 330 may receive the respective input signals (3D1, 3D2, and 3D3) that are input to each of the SLDs (311, 312, and 313), and output a signal indicative of the XOR function applied to such input signals. The output of the first XOR gate 330 is provided to the input of the first parity SLD 320. Operationally, the first XOR gate 330 may asynchronously calculate the parity of the signals (3D1, 3D2, and 3D3) that are input to the SLDs (311, 312, and 313) under test.

The first parity SLD 320 (also referred to herein as a parity test SLD) is illustrated as a D flip-flop that receives the output signal from the first XOR gate 330 at its D input, but the first parity SLD 320 may be any of a variety of different types of sequential logic device and/or other data storage element. The first parity SLD 320 may, for example, receive the same clock input signal (e.g., Clock_3) that is received by the SLDs (311, 312, and 313) under test. Operationally, the first parity SLD 320 captures the parity of the input signals (3D1, 3D2, and 3D3) as they are clocked into the SLDs (311, 312, and 313) under test.

The second XOR gate 340 receives as input the respective output signals from the SLDs (311, 312, and 313) under test and the output signal from the first parity SLD 320. The second XOR gate 340 thus asynchronously calculates the parity of the output signals from the SLDs (311, 312, and 313) under test and compares the calculated parity to the parity stored in the first parity SLD 320. The results of the test are output from the second XOR gate 340 as “Protect Group 3 Parity Error signal 341.” For example, operationally, if an output of one of the SLDs (311, 312, and 313) under test errantly changes, for example as a result of a soft error induced state change, such an errant change is reflected in the Protect Group 3 Parity Error signal 341. As discussed above with regard to the first XOR gate 330, the second XOR gate 340 may comprise a single XOR gate, an XOR tree, or any type of circuit that performs an XOR function. As illustrated by the output bubble labeled “B,” the Parity Group 3 Parity Error signal 341 is output to the corresponding input bubble labeled “B” in FIG. 1.

Referring briefly back to FIG. 1, the report point OR gate 150 receives as input the Protect Group 3 Parity Error signal 341. As mentioned previously, the first OR gate 150 may also receive as input respective Protect Group Parity Error signals from other parity protect groups. Please refer to the previous discussion of FIG. 1 for the discussion of the operation of the report point OR gate 150 and the report point SLD 160.

The parity protect group shown in FIG. 3 may, for example, be characterized by a respective set of control signal inputs. For example, the respective set of control signal inputs may comprise a clock net (e.g., clocked by the Clock_2 signal), a clear (or reset) net (e.g., a null net, since the SLDs 311, 312, and 313 of the electrical circuit 300 of FIG. 3 are not coupled to a clear signal), and a set (or preset) net (e.g., a null net, since the SLDs 311, 312, and 313 of the electrical circuit 300 of FIG. 3 are not coupled to a set signal). Such an example set of control signal inputs, for example based on three control signal nets, may also be referred to herein as a triplet. As was seen in the previous discussions of FIG. 1 and FIG. 2, other parity protect groups may be characterized by different respective sets of control signal inputs. Other parity protect groups may also be characterized by a same set of control signal inputs as the parity protect group shown in FIG. 3.

Note that the example parity protect groups, and their respective corresponding sets of control signal inputs, are merely examples. Other parity protect groups corresponding to other respective sets of control signal inputs are also within the scope of the present disclosure.

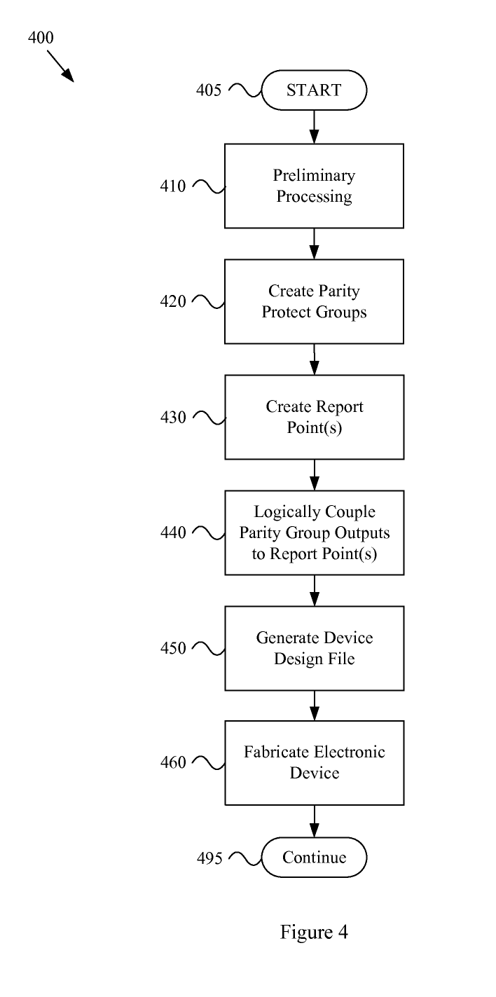

The previous discussion of FIGS. 1-3 provides examples of various circuit protection structures in accordance with various aspects of the present disclosure. The following discussion of FIGS. 4-6 provides example methods and systems for forming various circuit protection structures, for example those shown in FIGS. 1-3 and discussed previously.

Turning to FIG. 4, such figure shows a flow diagram of an example method 400 for protecting an electrical circuit, in accordance with various aspects of the present disclosure. The method 400 may, for example, comprise a method of producing an electronic device with on-board error detection.

The example method 400 begins executing at step 405, the method 400 may begin executing in response to any of a variety of causes or conditions. For example, the method 400 may begin executing in response to a user command to incorporate error protection circuitry in a design, for example as generated organically, received from a third party designer, etc. Also, for example, the method 400 may begin executing in response to a circuit design file being copied into a particular directory. Additionally, for example, the method 400 may begin executing in response to a customer request for the addition of error protection circuitry to a design. Further for example, the method 400 may begin executing in response to a simulation result indicating that more or less error protection is needed in a design, for example to meet particular error criteria (e.g., mean time before failure (MTBF) criteria). In general, the method 400 may begin executing in response to any of a variety of causes or conditions. Accordingly, the scope of various aspects of the present disclosure should not be limited by characteristics of any particular cause or condition, unless explicitly stated.

The example method 400 may, at step 410, comprise performing preliminary processing. Such preliminary processing may, for example, be performed on a circuit design prior to being parsed into parity protect groups. Step 410 may comprise performing any of a variety of types of preliminary processing, non-limiting examples of which will now be provided

Step 410 may, for example, comprise downloading and/or otherwise receiving circuit design information for a circuit design to which error protection is to be added. Such circuit design may, for example, be received in an RTL (register transfer level) design description file, or any of a variety of types of circuit design files. Step 410 may, for example, comprise receiving circuit design information from a design group of the enterprise implementing the method 400. Also for example step 410 may comprise downloading circuit design information from a third party enterprise (e.g., outside the control of the implementer of the method 400) that sells, licenses, or otherwise commercializes circuit designs that may be used by others.

Step 410 may further, for example, comprise converting a received circuit design file into a desired format for further processing. For example, in an example scenario in which an RTL design description file is received, step 410 may comprise converting such an RTL design description file into a gate level circuit representation (e.g., a gate level net list) for further processing.

Step 410 may also, for example, comprise receiving user input information, for example information that may govern execution of the method 400. For example, such user input may comprise receiving input directly from a user and/or from a configuration file. Such user input may, for example, comprise information regarding maximum size that a parity protect group may have, timing constraint information regarding allowable or preferred timing constraints for a circuit element (e.g., an SLD) included in a parity protect group, information regarding a minimum setup margin and/or clock-to-out margin allowable for an SLD included in a parity protect group, information regarding a target or MTBF for an electric circuit being protected, information regarding a percentage of circuit elements (e.g., SLDs) that need to be protected, etc.

In various example scenarios, there may be a maximum size allowed for a parity protect group. In an example implementation, a maximum number of SLDs under test is allowed for a particular parity protect group. In such an example scenario, step 410 may comprise determining such a maximum number. For example, step 410 may comprise receiving the maximum number via user input and/or reading the maximum number from a configuration file. Also for example, such a maximum number may be hard coded into software implementing the method 400. Additionally for example, step 410 may comprise determining the maximum number based on timing constraints (e.g., setup time or clock-to-out margin for parity test SLDs and/or SLDs under test). Such a maximum number may for example, be 64, 32, 128, etc. (or 63, 31, 127, etc., if an odd number maximum is desired).

Step 410 may also, for example, comprise identifying circuit elements (e.g., SLDs) that are eligible for inclusion in parity groups. For example, step 410 may comprise first generating a protect list comprising all SLDs of the electrical circuit (or device), and then removing from the protect list a set of SLDs for which inclusion in a parity protect group is not desired. For example, step 410 may comprise removing from the protect list all non-critical SLDs for which error detection is not needed, removing from the protect list SLDs that receive data from a clock domain other than a clock domain presently of interest (e.g., for which a report point is going to be generated) or that are otherwise associated with a different clock domain, and/or removing from the protect list SLDs that are already error protected in some other manner (e.g., by other parity protection, error detection circuitry, error correction circuitry, ECC or CRC or other codes, etc.).

As mentioned previously, various aspects of the disclosure may comprise forming a plurality of parity protect groups that are generally associated with a same clock domain (e.g., each parity protect group optionally includes or does not include various gated clock nets in such clock domain). Additionally, as discussed previously, parity protect groups may be formed in accordance with corresponding sets of control signal inputs (e.g., triplets, as discussed previously). In such an example scenario, step 410 may comprise, for example for each SLD in the protect list, identifying the respective set of control signal inputs. Information of the respective set of control signal inputs for each SLD may then, for example, be utilized in a subsequent step for parsing (or dividing or segregating) the SLDs into parity protect groups with other SLDs having same respective sets of control signal inputs. As mentioned previously, a set of control signal inputs may, for example, comprise any one or more of: a clock net, a clear (or reset) net, a set (or preset or load) net, etc.

Step 410 may further, for example, comprise generating a super parity protect group comprising all SLDs that have a same set of control signal inputs. In such an example scenario, a subsequent step (e.g., step 420) may comprise parsing (or dividing or segregating) the super parity protect group of SLDs into a plurality of parity protect groups, each of which comprising no more than the determined maximum number of SLDs under test (discussed above).

In general, step 410 may comprise performing preliminary processing, for example prior to assigning circuit elements (e.g., SLDs) to parity protect groups. Accordingly, the scope of various aspects of the present disclosure should not be limited by any particular manner of performing preliminary processing unless explicitly stated. It should also be noted that the discussion of various functionality with regard to step 410 does not necessarily mean that such functionality must be performed before subsequent steps as illustrated in FIG. 4. For example, any or all of the functionality discussed above with regard to step 410 may be performed at step 420 below or another step.

The example method 400 may, at step 420, comprise generating parity protect groups for an electrical circuit (e.g., of an electronic device) that are advantageously protected. Many example characteristics of parity protect groups have been discussed previously (e.g., with regard to FIGS. 1-3 and step 410).

For example, a parity protect group may comprise a plurality of SLDs under test, where each of the plurality of SLDs under test is coupled to a same set of one or more control signal inputs. The same set of control signal inputs may, for example, comprise: a same clock net, a same clear (or reset) net, a same set (or preset) net, etc. For example, a set of control signal inputs may comprise a triplet (clock, clear, set) of control signal input nets, where any one or more of the triplet of control signal input nets may be null (or not used). FIGS. 1-3 provide three respective examples of sets of control signal inputs. For example, in FIG. 1, the set of control signal inputs comprise a triplet of Clock_1 net, Clear_1 net, and Set_1 net. Also for example, in FIG. 2, the set of control signal inputs comprise a triplet of Clock_2 net, Clear_2 net, and null net. Additionally for example, in FIG. 3, the set of control signal inputs comprises a triplet of Clock_3 net, null net, and null net.

A parity protect group may also, for example, comprise a parity SLD. Example parity SLDs were illustrated in FIGS. 1-3 (e.g., at parity SLD 120, parity SLD 220, and parity SLD 320). The parity SLD may, for example, be coupled to the same set of control signal inputs to which the SLDs under test are coupled.

A parity protect group may additionally, for example, comprise a parity test output. Examples of a parity test output are provided in FIGS. 1-3 (e.g., at Protect Group 1 Parity Error 141, Protect Group 2 Parity Error 241, and Protect Group 3 Parity Error 341).

As discussed previously, a plurality of parity groups may be formed for a same set of control signal inputs. For example, step 420 may comprise generating a plurality of parity protect groups that all have the same set of control signal inputs. Also for example, as also discussed previously, any one or more of the plurality of parity groups may have different respective sets of control signal inputs (e.g., even within a same overall clock domain).

Further, as discussed previously, the parity protect groups may have different respective numbers of electrical elements (e.g., SLDs) under test. The number of SLDs under test, for example, might be generally odd. In various implementations, for example implementations utilizing the preset signal, it may be advantageous to subdivide the group of SLDs into smaller groups, each containing an odd number of SLDs. For example, in such a scenario, an always odd number of SLDs produces a known parity result in response to a set signal without having to know the number of SLDs under test.

In an example scenario, at least 75% of all parity protect groups, or at least 75% of all parity protect groups that correspond to a respective non-null preset net, generated at step 420 might have respective odd numbers of SLDs under test. In another example scenario, at least 90% of all parity protect groups, or at least 90% of all parity protect groups that correspond to a respective non-null preset net, generated at step 420 has respective odd numbers of SLDs under test. In still another example, 100% of all parity protect groups, or 100% of all parity protect groups that correspond to a respective non-null preset net, generated at step 420 might have respective odd numbers of SLDs under test.

As an alternative, in a scenario in which a protect group corresponds to a set of control signal inputs that includes a non-null preset net, the number of SLDs under test is set to an even number, and additional logic may be incorporated into the parity test circuitry. As an alternative, for example in a scenario in which a protect group corresponds to a set of control signal inputs that includes a non-null preset net and in which the protect group has an even number of SLDs under test, the logical OR of the clear and preset signals may be provided to the clear input of the parity SLD, and a logical 0 may be provided to the preset input of the parity SLD.

As mentioned above in the discussion of step 410, a maximum number of circuit elements (e.g., SLDs) under test allowed in a parity protect group may be determined (e.g., based on user input, etc.). In such a scenario, step 420 may comprise generating a plurality of parity protect groups, where none of the plurality of protect groups has more than the maximum number of circuit elements allowed. Many examples of such maximum numbers were provided previously.

As also mentioned above, a parity protect group may comprise a parity test output signal. As illustrated in FIGS. 1-3, such a parity test output signal may be output from an XOR gate (140, 240, and/or 340) or XOR tree that receives as inputs an output from the parity test SLD of the parity protect group and respective outputs from each of the SLDs under test of the parity protect group.

Step 420 may, for example, comprise selecting circuit elements (e.g., SLDs) for the protect groups based, at least in part, on a timing constraint (e.g., an SLD timing constraint). An example of such a timing constraint may comprise setup margin and/or a clock-to-out margin for an SLD. In an example scenario, in which a portion of the SLDs need to be protected, but not all of the SLDs need to be protected, step 420 can select the SLDs that are incorporated in parity protect groups. Since the addition of testing devices (e.g., the first XOR gates 130, 230, and 330 illustrated in FIGS. 1-3) may slow down signal transitions (e.g., of the SLDs under test), for example by adding additional capacitance and/or leakage to an input and/or output signal line, step 420 may comprise incorporating SLDs with the loosest timing constraints (e.g., having the largest setup margins and/or clock-to-out margins, or path slack) into the parity protect groups. In such a scenario, a portion of the SLDs with the tightest timing constraints (e.g., having the smallest setup margin and/or clock-to-out margin, or path slack) might not be included in a parity protect group.

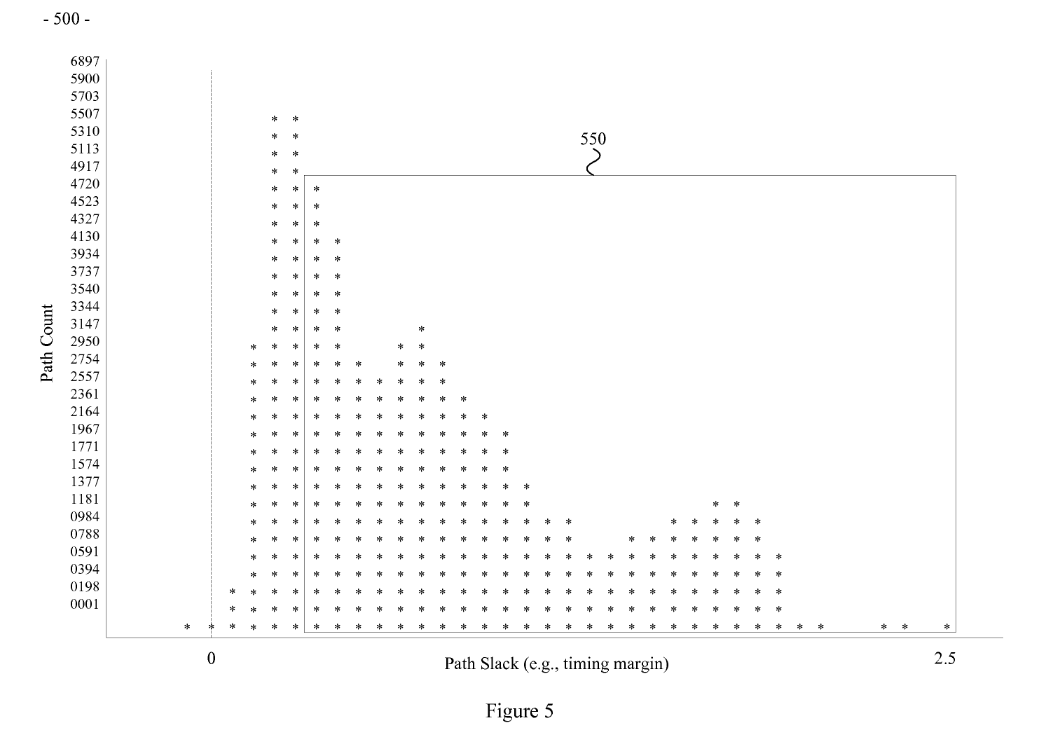

Portions of the following discussion refer to FIG. 5, which shows a diagram 500 illustrating circuit component selection, in accordance with various aspects of the present disclosure. The diagram 500 generally shows a histogram chart of path slack (or setup margin) for various signal paths (and their respective components) for a particular example circuit. For example, as discussed above, step 420 of FIG. 4 may comprise incorporating SLDs with the loosest timing constraints (e.g., having the largest set up margins or path slack) into the parity protect groups. Referring to FIG. 5, such SLDs may correspond to the right portion of the diagram 500 (e.g., those SLDs corresponding to the paths enclosed in box 550).

Step 420 may comprise selecting circuit elements (e.g., SLDs) for the protect groups based, at least in part, on a timing constraint (e.g., an SLD timing constraint) in any of a variety of manners, non-limiting examples of which are now provided. For example, step 420 may comprise excluding from the plurality of parity protect groups, those SLDs having respective timing constraints that are less than a threshold timing constraint (e.g., those SLDs corresponding to the paths in FIG. 5 to the left of the left side of box 550). For example, step 420 may comprise excluding those SLDs that have a setup margin of less than N microseconds, instead including those SLDs having a setup margin of N microseconds or greater, and/or excluding those SLDs that have a clock-to-out margin of less than M microseconds, instead including those SLDs having a setup margin of M microseconds or greater, etc.

Also for example, step 420 may comprise including in the plurality of parity protect groups a first set of SLDs having respective timing constraints (e.g., those SLDs corresponding to the paths in FIG. 5 that are in box 550), and excluding from the plurality of parity protect groups a second set of SLDs having respective timing constraints that are tighter than the respective timing constraints for the first set of SLDs (e.g., those SLDs corresponding to the paths in FIG. 5 that are to the left of box 550).

Additionally for example, step 420 may comprise selecting circuit elements (e.g., SLDs) for the plurality of parity protect groups by, at least in part, including in the plurality of parity protect groups a first set of SLDs having acceptably large (or otherwise sized) respective timing constraints (e.g., those SLDs corresponding to the paths in FIG. 5 that are inside box 550), and excluding from the plurality of protect groups a second set of SLDs having unacceptably small (or otherwise sized) respective timing constraints (e.g., those SLDs corresponding to the paths in FIG. 5 that are outside of box 550).

As mentioned previously, in various scenarios it is not necessary to protect all circuit elements (e.g., SLDs) to achieve a desired reliability goal (e.g., to meet an MTBF target, for example input by a user, required by a customer, etc.). In such a scenario, step 420 may comprise determining a target percentage of SLDs of the electrical circuit (or device) to parity check to reach the desired level of reliability. Such determining may, for example, comprise receiving the target percentage as user input, determining the target percentage based on simulation results, determining the target percentage based on field failure results, etc. In such a scenario in which a target percentage (e.g., N %) has been identified, step 420 may comprise selecting N % of the SLDs having the loosest relative timing constraints for inclusion in the parity protect groups. For example, in a scenario in which it has been determined that 75% or 95% or 99% of the SLDs of a circuit must be protected to achieve a minimum acceptable MTBF, step 420 may comprise identifying the 75% or 95% or 99% of the SLDs of the circuit that have the highest clock-to-out margin and/or highest setup margin (or path slack), etc.

Step 420 may comprise generating parity protect groups based, at least in part, on any of a variety of criteria, non-limiting examples of which are presented above. Other example criteria may, for example, comprise physical location in a circuit, type of component, etc.

In general, step 420 may comprise generating parity protect groups for an electrical circuit (e.g., of an electronic device) that is advantageously protected. Accordingly, the scope of various aspects of the present disclosure should not be limited by characteristics of any particular manner of generating the parity protect groups unless explicitly stated.

The example method 400 may, at step 430, comprise generating a report point. Such a report point may, for example comprise a report point SLD that outputs parity test results for the parity protect group. Examples of such a report point SLD are provided at FIGS. 1-3 (e.g., at report point SLD 160, report point SLD 260, and report point SLD 360). As discussed previously, for example with regard to FIGS. 1-3, a single report point might be used as a sole reporting point for a particular clock domain. Alternatively, a plurality of report points may be used for a particular clock domain.

As illustrated in FIGS. 1-3, a report point may be utilized to report a parity error that has occurred in any of a plurality of parity protect groups. Note that such parity protect groups might all be associated with a same set of control signal inputs (e.g., a same triplet), or may be associated with one or more different respective sets of control signal inputs (e.g., as shown by example in FIGS. 1-3).

The example method 400 may, at step 440, comprise logically combining each of the respective parity test outputs of the plurality of parity protect groups at an input of the report point SLD(s). For example, as illustrated in FIGS. 1-3, a report point OR gate 150 may be utilized to logically combine the Protect Group 1 Parity Error 141, Protect Group 2 Parity Error 241, and Protect Group3 Parity Error 341 outputs and provide the logically combined (e.g., the OR'd) output to the input of the protect point SLD 160. As discussed previously, the priority protect OR gate 150 may, for example, be a single logic gate, an OR tree, any circuit performing an OR function, etc.

The example method 400 may, at step 450, comprise generating a circuit (or device) design file, or other form of design information. Step 450 may, for example, comprise generating a gate level design description (e.g., a gate level net list) and/or any of a variety of other types of design descriptions. For example, step 450 may comprise generating a file comprising a description (or source code) that when processed by one or more processors of an integrated circuit (IC) fabrication system, causes the described electrical circuit to be fabricated. Note that such fabrication may comprise many intermediate steps between design file and completed circuit.

Step 450 may comprise storing the circuit design file (or other information) on a storage medium (e.g., a non-volatile storage medium). For example, step 450 may comprise storing the circuit design file on a hard drive, solid state drive, flash drive, CD ROM, DVD ROM, memory stick or thumb drive, etc. Step 450 may also, for example, comprise communicating the circuit design file (or other information) to another computing system (or computer system site) via any of a variety of types of communication networks.

The example method 400 may, at step 460, comprise fabricating the electronic circuit (or device) comprising said plurality of parity protect groups and said report point(s). The electronic device may, for example, also comprise the logical coupling circuitry discussed previously at step 440. Step 460, for example, may comprise fabricating the electronic circuit utilizing any of a variety of techniques, for example based on a circuit design file generated at step 450.

The example method 400 may, at step 495, comprise performing continued operations. Such continued operations may comprise characteristics of any of a variety of continued operations. For example, step 495 may comprise looping execution flow of the example method 400 to any previous step or sub-step discussed herein.

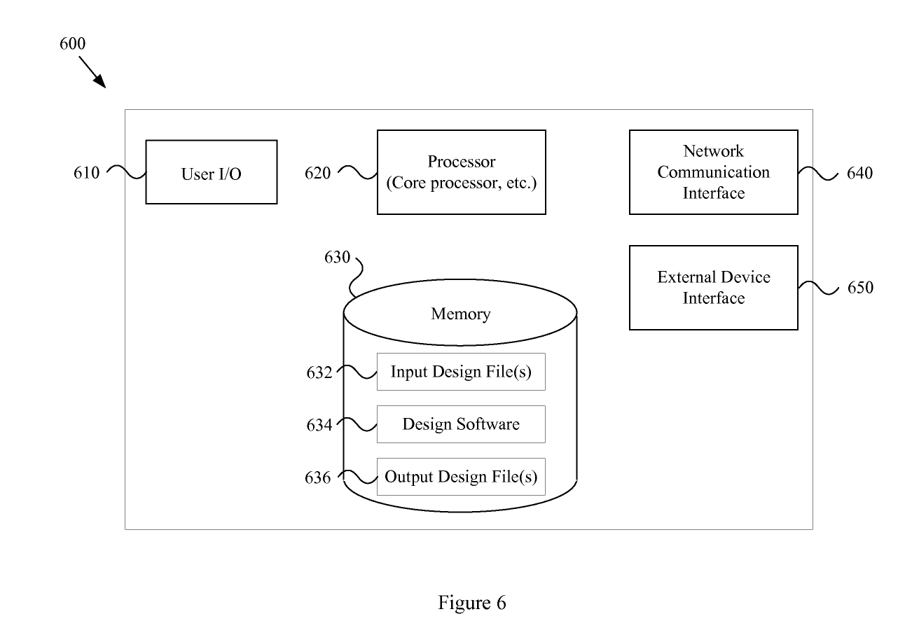

In general, any or all aspects of the example method 400 may be performed in an automated environment (e.g., free of user interaction during execution of the method 400). An example of such an automated environment is shown at and described in relation to FIG. 6.

Turning to FIG. 6, such figure is a diagram illustrating a system 600 for protecting an electrical circuit, in accordance with various aspects of the present disclosure. The system 600 (e.g., any or all components thereof) may operate to perform any or all aspects of the example method 400 illustrated in FIG. 4 and discussed previously and/or any other functionality discussed herein.

The system 600, for example, comprises a user I/O module 610. The user I/O module 610 may, for example, operate to perform any or all user interface functionality discussed herein (e.g., with regard to at least step 410 and/or any of the steps of FIG. 4). The system 600 may also, for example, comprise a Network Communication Interface module 640. The Network Communication Interface module 640 may, for example, operate to perform any or all communication network interface functionality discussed herein. The system 600 may further, for example, comprise an External Device Interface module 650. The External Device Interface module 650 may, for example, operate to perform any or all functionality discussed herein regarding communication with external (or peripheral devices), for example disk drives and/or electronic device fabrication equipment.

The system 600 also, for example, comprises one or more processors 620 and one or more memory 630 devices. For example, a processor 620 may operate to perform any or all functionality discussed herein by, at least in part, executing software instructions stored as design software 634 in the memory 630. Also for example, the processor 620 may execute the design software 634 to process one or more input circuit design files 632 stored in the memory 630 and generate one or more output design files 636 stored in the memory 630. The processor 620 may, for example, communicate the output design files 636 (for example output from the method 400 of FIG. 4) to another system (e.g., via the Network Communication Interface module 640). The processor 620 may also, for example, store the output design files 636 on a non-volatile computer readable medium (e.g., using the External Device Interface).

As mentioned above, the processor 620 may operate in accordance with the design software 634 to implement any or all aspects of the method 400 of FIG. 4. The design software may, for example, reside in non-volatile memory of the system 600 (e.g., a magnetic and/or optical disk drive, a flash drive, a CD ROM drive, a DVD ROM drive, etc.).

The system 600 may, for example, be a system contained in a single chassis or may, for example, be a distributed system comprising components that are dispersed throughout a building, campus, metropolitan area, nation, world, etc. Components of a distributed system may, for example, be communicatively coupled via any of a variety of intervening communication networks (e.g., the Internet, a metropolitan area network, a local area network, a wired and/or wireless network, terrestrial or satellite communication network, etc.).

The system 600 is shown in FIG. 6 parsed into separate functionality modules for illustrative clarity only. The various aspects of the system 600, however, need not be segregated. For example, the modules may comprise shared hardware and/or software. Also for example, the processor 620 may operate to perform the functionality of any of the other illustrated modules. Accordingly, the scope of various aspects of this disclosure should not be limited by arbitrary boundaries between hardware and/or software components, unless explicitly stated.

In summary, various aspects of the present disclosure provide a system and method for providing error protection in an electrical circuit. While the foregoing has been described with reference to certain aspects and embodiments, it will be understood by those skilled in the art that various changes may be made and equivalents may be substituted without departing from the scope of the invention. For example, within this document, the flops are illustrated as D-flops with set and clear input signals. However, the scope of various aspects of this disclosure should not be limited by characteristics of such flops. For example, the various aspects of this disclosure readily apply to any of a variety of different types of flops (e.g., SR flops, JK flops, T flops, etc.) having any of a variety of respective types of inputs (e.g., clear or reset inputs, set or preset or load inputs, etc.). For example, some systems may use reset and clear signals that are interchangeable. In another example, some systems may use reset and clear signals that are not interchangeable. In a further example, some systems may use set, preset, and/or load signals that are interchangeable. In an additional example, some systems may use set, preset, and/or load signals that are not interchangeable. In such instances, one of skill in the art will readily appreciate that the various aspects of this disclosure apply to all types of flops and/or all types of respective inputs for such flops. Many modifications may be made to adapt a particular situation or material to the teachings of the disclosure without departing from its scope. Therefore, it is intended that the invention not be limited to the particular embodiment(s) disclosed, but that the invention will include all embodiments falling within the scope of the appended claims.

What is claimed is:

1. A method of producing an electronic device with on-board error detection, the method comprising:
generating a plurality of parity protect groups, where each of the plurality of parity protect groups comprises:
a number of storage elements under test, each of which is coupled to a same set of control signal inputs comprising: a same clock net, a same clear net, and a same preset net;
a parity test storage element coupled to said same set of control signal inputs; and
a parity test output;
generating a report point comprising a report point storage element that outputs parity test results;
logically combining each of the respective parity test outputs of each of the plurality of parity protect groups at an input of the report point storage element; and
fabricating the electronic device comprising said plurality of parity protect groups and said report point,
wherein:
the plurality of parity protect groups are all associated with said same set of control signal inputs; and
the respective number of storage elements under test of each of the plurality of parity protect groups is an odd number.

2. The method of claim 1, wherein each of the plurality of parity protect groups comprises an XOR tree that outputs the parity test output and receives as inputs an output from the parity test storage element of the parity protect group and respective outputs from each of the storage elements under test of the parity protect group.

3. The method of claim 1, comprising, prior to said generating a plurality of parity protect groups, determining a maximum number of storage elements under test for each of the plurality of parity protect groups, and wherein the respective number of storage elements under test for each of the plurality of parity protect groups is no more than the determined maximum number.

4. The method of claim 1, wherein at least 75% of all parity protect groups of the electronic device that correspond to a respective non-null preset net have a respective odd number of storage elements under test.

5. The method of claim 1, comprising, prior to said generating a plurality of parity protect groups generating a protect list comprising all storage elements of the electronic device less at least a set of storage elements for which inclusion in a parity protect group is not desired.

6. The method of claim 1, wherein said plurality of parity protect groups are associated with a same clock domain.

7. The method of claim 6, comprising, prior to said generating a plurality of parity protect groups, identifying a respective set of control signal inputs for at least each storage element in the same clock domain that is to be included in a parity protect group.

8. The method of claim 1, comprising, prior to said generating a plurality of parity protect groups:
determining a maximum number of storage elements under test for each of the plurality of parity protect groups; and
generating a super parity protect group having more than the determined maximum number of storage elements, and associated with the same set of control signal inputs,
wherein said generating a plurality of parity protect groups comprises parsing said super parity protect group into the plurality of protect groups, each of which comprising no more than the determined maximum number of storage elements under test.

9. The method of claim 1, wherein said generating a plurality of parity protect groups comprises selecting storage elements for the plurality of parity protect groups based, at least in part, on a storage element timing constraint.

10. The method of claim 9, wherein said storage element timing constraint comprises at least one of: storage element setup margin and/or storage element clock-to-out margin.

11. The method of claim 9, wherein said generating a plurality of parity protect groups comprises excluding from the plurality of parity protect groups storage elements having respective timing constraints that are less than a threshold timing constraint.

12. The method of claim 9, wherein said generating a plurality of parity protect groups comprises:
determining a target percentage of storage elements in a circuit design to parity check to reach a desired level of reliability; and
identifying the target percentage of storage elements in the circuit design generally having the loosest timing constraints for inclusion in the parity protect groups.

13. A method of producing an electronic device with on-board error detection, the method comprising:
generating a plurality of parity protect groups, where each of the plurality of parity protect groups comprises:
a number of storage elements under test, each of which is coupled to a same set of control signal inputs;
a parity test storage element coupled to said same set of control signal inputs; and
a parity test output;
generating a report point comprising a report point storage element that outputs parity test results; and
fabricating the electronic device comprising said plurality of parity protect groups and said report point,
wherein said generating a plurality of parity protect groups comprises selecting storage elements for the plurality of parity protect groups based, at least in part, on a storage element timing constraint.

14. The method of claim 13, wherein said storage element timing constraint comprises at least one of: storage element setup margin and/or storage element clock-to-out margin.

15. The method of claim 13, wherein said selecting storage elements for the plurality of parity protect groups comprises:
including in the plurality of parity protect groups a first set of storage elements having acceptably sized respective timing constraints; and
excluding from the plurality of parity protect groups a second set of storage elements having unacceptably sized respective timing constraints.

16. The method of claim 13, wherein said selecting storage elements for the plurality of parity protect groups comprises:
determining a target percentage of storage elements in a circuit design to parity check; and
identifying the target percentage of storage elements in the circuit design generally having the loosest timing constraints for inclusion in the parity protect groups.

17. A method of producing an electronic device with on-board error detection, the method comprising:
generating a plurality of parity protect groups, where each of the plurality of parity protect groups comprises:
a number of storage elements under test, each of which is coupled to a same set of control signal inputs comprising a same clock net;
a parity test storage element coupled to at least a portion of said same set of control signal inputs; and
a parity test output;
generating a report point comprising a report point storage element that outputs parity test results;
logically combining each of the respective parity test outputs of each of the plurality of parity protect groups at an input of the report point storage element; and
fabricating the electronic device comprising said plurality of parity protect groups and said report point,
wherein the plurality of parity protect groups are all associated with said same set of control signal inputs.

18. The method of claim 17, wherein the same set of control signal inputs comprises the same clock net, a same clear net, and a same preset net.

19. The method of claim 18, wherein for each of the plurality of parity protect groups, the number of storage elements under test is an odd number.

20. The method of claim 18, wherein for each of the plurality of parity protect groups that have an even number of storage elements:
a clear input of the parity test storage element is connected to a logical OR of the same clear net and the same preset net; and
a preset input of the parity test storage element is connected to a logical 0.
